(19) United States
(12) Patent Application Publication
(10) Pub. No.: US 2022/0238412 A1
(43) Pub. Date: Jul. 28, 2022

(54) ELASTIC THERMAL CONNECTION STRUCTURE

(71) Applicant: DTEN, Inc., San Jose, CA (US)

(72) Inventors: Wei Liu, San Jose, CA (US); Jin Guo, San Jose, CA (US); Rui Xu, San Jose, CA (US)

(21) Appl. No.: 17/572,974

(22) Filed: Jan. 11, 2022

Related U.S. Application Data
(60) Provisional application No. 63/140,438, filed on Jan. 22, 2021.

(51) Int. Cl. H01L 23/373; H01P 1/18

(52) U.S. Cl. CPC H01L 23/3733; H01L 25/0655; H01P 1/18

(57) ABSTRACT

A thermal connection structure includes a foam layer having a light porous, semi-grid flexible material. A thermal conducting medium is injected within closed cells and foam voids of the foam layer. A heat dissipating layer couples the thermal conducting medium comprising a planar unsaturated ring that has thermal conductivity that couples a heat sink.

### 1. PRIORITY CLAIM

This application claims the benefit of priority to U.S. Provisional Application No. 63/140,438 filed Jan. 22, 2021, titled “Elastic Thermal Connection Structure,” and is related to U.S. Application No. 17/_ filed Jan. 11, 2022, filed under attorney docket number 20008C titled “Active Thermal Dissipating System”, and U.S. Application No. 17/_ filed Jan. 11, 2022, filed under attorney docket number 49809-20008D, titled “Flexible Thermal Connection Structure,” all of which are herein incorporated by reference in their entireties.

### BACKGROUND OF THE DISCLOSURE

### 2. Technical Field

This disclosure relates heat dissipation, and in particular to temperature control systems.

### 3. RELATED ART

Electronic devices are susceptible to failure. Some are caused by mechanical stress and others by thermal stress. Long periods of stress can decrease electronic device longevity and reliability. It can cause integrated circuits to break down and electronic devices to fail.

With higher circuit densities, many electronic devices and chips have smaller surface areas that generate more heat. Some electronic devices throttle performance to keep temperatures down when safe operating conditions cannot be maintained. A throttling state can cause a device to reduce its power draw and/or reduce its clock speed to address poor temperature management. In the end, throttling causes electronic devices not to perform at their best, sometimes leaving processing tasks uncompleted, and worse, shutting down time sensitive applications.

Outside temperatures also affect an electronic device's temperature management and create adverse operating conditions. As temperatures rise, such as when devices are exposed to sunlight, internal device temperatures may rise at a much faster rate than under normal operating conditions putting the electronic device at risk. When the temperatures get too high or increase at non-compensable rates, the electronic devices can be permanently damaged.

Like extreme heat, extreme cold and moisture also affect electronic devices. With most temperature management devices not remediating broad temperature conditions, the device's cooling solutions cannot compensate or insulate electronic devices from cold conditions to maintain a safe operating state or protect devices from moisture. Low temperatures and condensation can cause sudden and unexpected system shutdowns and damage devices.

### BRIEF DESCRIPTION OF THE DRAWINGS

The disclosure can be better understood with reference to the following drawings and description. The components in the figures are not necessarily to scale, emphasis instead being placed upon illustrating the principles of the invention. Moreover, in the figures, like referenced numerals designate corresponding parts throughout the different views.

FIG. 1 is an elastic thermal connection structure.

FIG. 2 is another elastic thermal connecting structure.

FIG. 3 is a front view of the elastic thermal connection structure.

FIG. 4 is a heat dissipating layer.

FIG. 5 is a top view of an outer layer.

FIG. 6 is a bottom view of the outer layer.

FIG. 7 is a side view of another elastic thermal connection structure.

FIG. 8 is a front view of a heat dissipating layer formed by stress.

FIG. 9 is a sectional view of a heat dissipating layer formed by stress.

FIG. 10 is a cross-sectional view of another elastic thermal connection structure.

FIG. 11 is an exploded view of a multilayer foam.

FIG. 12 is a cross-sectional view of multilayer foams contrasting lateral grain orientations reinforced with a grain boundary strengthening.

FIG. 13 is an exploded view of a machine.

FIG. 14 is an exploded view of another machine.

FIG. 15 is a structural diagram of a machine.

FIG. 16 is exploded view of another machine.

### DETAILED DESCRIPTION

A temperature control system compensates for mechanical and thermal stress. Using homogeneous flexible layers in some systems, and mixed density flexible layers (e.g., inhomogeneous materials) in some other systems, the temperature control system (also referred to as an elastic thermal connection structure(s) or machine structure(s)) provides thermal diffusivity and vibration compensation for electronic devices. The system's thermal diffusivity varies with the density and porosity of the homogeneous flexible layer and thermal conductivity of the heat dissipating layer in some systems and with the variable relative density and porosity of flexible materials and the thermal conductivity of the heat dissipating layer in some other systems.

Using combinations of low and/or high thermal conductivity flexible materials, the systems control the heat transfer rates thorough electronic devices. When a foam layer (e.g., a light, porous, semi-grid physical material) is used, the electrical insulating and thermal conducting medium or mediums that is/are injected within the foam's closed cells and/or voids (referred to as the void medium or filler) or are part of the foam itself becomes more excited as the temperature increases. As temperature increase, convection increases within the foam and between the cells and the voids, increasing the thermal convection and heat transfer flow to an outer layer that dissipates the heat to an open area or through a heat sink or radiator.

In some systems, the thermal conductivity of the foam layer is substantially continuous when the foam and the void medium within the closed cells and voids comprise homogeneous thermal conductors, respectively. In other systems, the thermal conductivity across electronic devices vary due to the foam layer's inhomogeneity, grain structure, and/or the various thermal conducting properties of the different mediums used within different parts of the foam, or enclosed in different cells and/or voids and the thermal conductivity of the heat dissipating layer.

In some systems, the foam layers use high thermal conducting materials in some parts and insulating materials in other parts of the foam layers. Some foam uses amorphous mediums within the foam itself, and/or enclosed within cells and/or voids that vary near or at different parts of a circuit, electronic components, and/or an electronic device. In some systems, porosities of 60%, 65% and 70% in the closed cell systems achieved similar compressive energy absorption capacities. In those systems, temperature control systems having a mean foam pore size value at and/or lies between any value or interval within about 100-200 μm and a density of about 5 mg⁻³ possess a strong combination of strength, thermal conductivity, and energy absorption. The disclosed systems foam porosity size and materials described herein, such as void mediums, are not a design choice as each achieves a particular result such as increasing heat diffusivity, increasing vibrational resistance, and/or increasing electrical resistance, respectively, for example. They serve different functions that affect temperature control and electronic device performance.

When inert gases comprise some or part of a void medium, for example, the temperature control system may also show sharp changes in thermal conductivity when temperatures fall below the gas' dew point. Thermal conducting mediums that are a unitary part of the foam itself and/or comprise void medium or fillers include gasses that have strong thermal conductivity such as gases that have greater conductivity than about of 20 W/m-° C. at atmospheric pressure like hydrogen, amorphous and/or crystalline minerals such as graphene (e.g., having a thermal conductivity at ambient temperature of 2000-4000 m⁻¹ K⁻¹, which is the highest known of any material). A twenty five percent volume of a graphene filler in a silicon foam matrix results in a six percent increase in thermal conductivity. While extrinsic thermal conductivity is limited by impurities, defects, and boundaries, the thermal conductivity of amorphous carbon used in some temperature control systems is 0.01 m⁻¹ K⁻¹, supported graphene is 600 m⁻¹ K⁻¹, diamond is 2000 m⁻¹ K⁻¹, carbon nanotubes is 2300 m⁻¹ K⁻¹, and suspended graphene is 2000 m⁻¹ K⁻¹.

Thermal conducting mediums that are a unitary part of the foam itself and/or comprise void medium or fillers also include synthetic graphite, etc. (e.g., having a thermal conductivity of 1.3 W m⁻¹ K⁻¹ or greater, and/or poor electronic conductors such as naturally occurring or synthetic diamonds, silver, fused quartz, and/or mica, and/or phyllosilicate, etc., and/or other materials, gases, and each respective combination (e.g., adding Ag to GF (a mixture of Gf/Ag) increase thermal conductivity of the temperature control system by more than fifty percent from when graphene itself was used, etc.), in different forms (e.g., crystalline flakes, amorphous, etc.), some having conductive properties and others having insulating properties. When graphene is used in the temperature control system, its electrical resistance changes with the addition of metallic particles. The electrical resistance increases with temperature.

In some systems, the foam or foam layers (referred to as the foam layer) provide different properties that provide different electrical protections, thermal protections, vibration protections, and/or environmental protections for different parts of a circuit, component and/or electronic device (referred to as the electronic device(s)) that it couples in some systems and/or directly physically contacts in some other alternate systems. At some locations in the electronic device, the foam layer is water resistant, in some locations it has a high porosity and/or impregnated or includes one or more strong or weak thermal conductors and in some locations includes one or more poor electric conductors or strong insulators. In some locations it is flexible, vibration resistant, and/or flame resistant protecting electronic devices from vibrations, moisture, fire and/or contaminants. Some temperature control systems use varying foam-cell structures, geometries, and/or open cells in a unitary layer(s)/piece to provide different properties to different parts or portions of the electronic device or at different locations above or below electronic device.

Some foam layers provide insulating properties that insulate some parts from cold conditions by retaining heat and/or provide a moisture resistance to maintain the electronic device's safe operating state. Others foam layers comprise two or more portions that protect electronics from contaminants, but do not impede air flow (acting as a fine-grade filter). Some foam comprises closed-cells enclosing and/or supporting the void medium making it durable, flexible, pliable, yet dense and strong enough to conform to the irregular shapes and geometries that make up various integrated circuits, chips, electronic components, electronic circuits and/or optical components, etc. (referred to as chips).

Some systems are lined with, integrated with, or include a damping material that is a unitary part of or embossed in the foam that exhibits elastic properties. Some systems have viscous properties and other systems have a low resistance to deformation. Some damping materials used in the temperature control systems are less than about 0.050 in thick flexible material that has a foam density of 2 lbs./ft³ and a damping weight of 0.33 lbs./ft.² but substantially reduce device or environmentally-induced vibrations (having an 80% vibration reduction in some applications) that can cause destructive resonance to device, component, and/or circuit connections (such as solder joints and lead connections). At lower temperatures, fused quartz was used as its vibration damping properties did not decrease with temperature.

Some vibration and sound absorbing mediums are electrically tuned to specific frequency ranges. That is they serve as a mechanical equivalent to an electrical notch filter, a lowpass filter, and/or a high pass filter. In these systems, the tuning that comes from the structure and materials used such as the void medium connected/isolated by the foam. In these systems, the foam and void medium respond or act like a notch filter (e.g., the mechanical equivalent of a resistor coupled to an inductor coupled to a capacitor in series that couples ground), a low pass filter (e.g., the mechanical equivalent of a resistor coupled to a capacitor in series that couples ground), or a high pass filter (e.g., the mechanical equivalent of a capacitor coupled to a resistor in series that couples ground) that attenuates or absorbs frequencies in specific frequency ranges (e.g., such low frequencies that are created by a power supply/sources, transient noises, air flow, etc., for example), and pass others frequencies above and/or below a frequency band unaltered like an aural passband.

The electrically tuned/attenuated frequency band of the temperature control system (aka elastic thermal connection structures) by using a combination of materials high in conductance, inductance, and/or resistance is especially beneficial to audio devices that are susceptible to interfering signal frequencies. The foam and void medium's properties (e.g., the electrical conductance of the foam and the resistance, capacitance, and inductance of the void medium that simulate the circuit components) remove or dampen interfering frequencies and noise while passing desired frequencies. A noise comprises an undesirable signal, an undesired change in a waveform, or a distortion that may result in a loss of information or disrupts processing. Tuning is achieved by modifying the electrical conductance of a conductive foam (e.g., modifying the amount of carbon injected into the foam) that make the connections and modifying the resistive, inductive, and capacitive properties of one or more void medium by selection and amounts. In some systems, electrically conducting foam connections are isolated from other connections by using isolating foam in the foam inner layer.

A heat dissipating layer couples the outer layer of the foam. The heat dissipating layer may comprise multiple layers of graphite or a single conductive layer such as a one-atom-thick aromatic (e.g., a planar unsaturated ring of atoms) crystal. When multiple layers are used in some systems, each layer may comprise carbon atoms linked together in a hexagonal lattice. The links are covalent bonds separated by only about 0.142 nanometers. The atoms may be linked to sp2 hybridized bonds, in a single layer of atoms, two dimensionally. Each two dimensional, one atom thick layer of sp2 bonded carbon items is separated by about 0.335 nm. The sp2 hybridization comprises a mixing of one “s” to two “p” atomic orbitals, which involves the promotion of one electron in the “s” orbital to one of the “2p” atomic orbitals. In other systems, a two-dimensional carbonaceous material are arranged in hexagonal flat layers. In some systems, the single layer of sp2 bonded carbon atoms arranged in a honeycomb (hexagonal) lattice couples the outer layer. The single layer is practically transparent because the optical absorbance of graphene is about 2.3% making it hard to visualize. Specific properties of the graphene used in some temperature control systems, in contrast to some two-dimensional systems, remain the same even at room temperature, do not require a high thermal energy to activate. Like carbon nanotubes, the graphene used in some other temperature control systems has a high strength and is stronger than steel (e.g., a one atom thick layer of sp2 bonded carbon is three hundred times stronger than A36 structural steel at 130 gigapascals), has a high stretchability making it a flexible thermal conductor, and has a very high thermal conductivity which is even higher than metallic silver.

In some systems, the single, or multi-layer graphite or graphene (referring to a bi-layered, few-layered having a number of layers ≤10), or more than 10 all collectively referred to as a sheet) comprises the heat dissipating layer couples or entirely/fully/completely encloses and/or wraps the foam inner layer. Tension shapes the heat dissipating layer to the geometries of the electronic devices. In some systems, a single layer of the multi-layer graphite passes through a double-sided rubberized polymer polyethylene terephthalate (“PET”) film. The multilayer graphite is positioned near a bonding surface. The system's edge banding is formed by another layer of multi-layer graphite or graphene through and a single-sided adhesive or a spray film.

In some systems, a first adhesive area is positioned on a portion of the top surface of an outer layer of the heat dissipating layer, and a second adhesive area is positioned near or at the middle of a top surface of the outer layer. The opposite sides of the top surface of the outer layer includes a third adhesive area. The first adhesive area, the second adhesive area, and the third adhesive area receive a fastener or a double-sided rubberized PET sheet or other adhesives.

When the heat dissipating layer is under sufficient tension, the top surface of the heat dissipating layer can assume and maintain a curved-like or angular-like shape that renders an inner wall in some systems. The first adhesive area and the third adhesive area comprise a bottom surface of the inner wall, and the second adhesive area comprises the top surface of the inner wall. The bottom surface of a foam inner layer bonds to the bottom surface of the inner wall, and the top surface of the foam inner layer bonds to the top surface of the inner wall. In some systems, a portion of a bottom surface of the heat dissipating layer includes a fourth adhesive area, and an opposite portion of the bottom surface of the outer layer includes a fifth adhesive area. When multi-layer graphite sheets form the heat dissipating layer, tension forms the outer wall of the outer layer that includes rounded transitions. The fourth adhesive area and the fifth adhesive area comprise the bottom surface of an outer wall of the outer layer.

In some other systems, a foam inner layer comprises a single-layer and/or multiple layers having substantially the same cross sections. In other systems, the temperature control system or thermal connection structure is part of a machine structure. The machine structure includes a shell and one or more chips and/or electrical components. In these exemplary systems, the shell's wall further comprises the heat dissipating layer that functions like a heat sink.

In other machine structures, one or more integrated circuits and/or electrical components are fixed within a housing. The elastic thermal connection structure is arranged between and couples the one or more chips and the heat dissipating layer that functions as a heat sink. In some systems, the bottom surface of the outer wall of the outer layer of the heat dissipating layer is bonded to the plurality of integrated circuits, electronic chips, and/or components (also referred to as chips) via a compressible media like the disclosed foam. Alternatively, one or more chips are fixed on or within the housing. The one or more chips are coupled to a board, which couples the elastic thermal connection structure.

A bottom surface of the outer wall of the outer layer couples the installation platform. In other systems, one or more chips couple a housing. In an exemplary system, the one or more chips couple a one-atom-thick aromatic crystal, or alternatively, two or more than two one-atom-thick aromatic crystals via a foam that comprise a connecting sheet. The elastic thermal connecting structure is arranged between the one-atom-thick aromatic crystal and a heat sink. In the exemplary system, a bottom surface of one-atom-thick aromatic crystal is bonded to a graphite connecting piece. Alternative systems use silica gel thermal pads arranged between the bottom of the mounting platform and the plurality of chips and between the chips and the elastic thermal connection structure to provide electrical insulation.

Another elastic thermal connection structure includes a graphite sheet outer layer and a foam inner layer. The graphite sheet outer layer wraps and encloses the entire foam inner layer. In the exemplary system, artificial graphite and foam materials are compounded or aggregated to form a unitary elastic thermal connection with good elasticity and good thermal conductivity. An electrically and/or thermally tuned thermal convection ensure a highly efficient conductive medium between the heating components (e.g., circuits, chips, etc.) and the exposed heat dissipation components. The system's elasticity ensure a stable and reliable thermal connection between the electrical components and the external heat dissipation components. In cooling applications, the system's low thermal resistance ensure efficient passive heat dissipation and strong thermal conductivity to sustain a safe operating state.

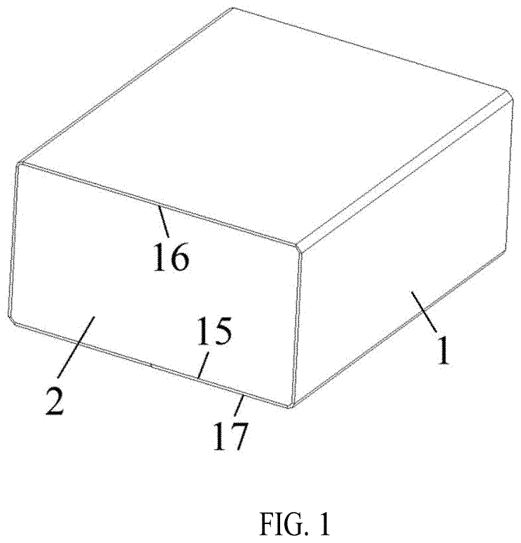

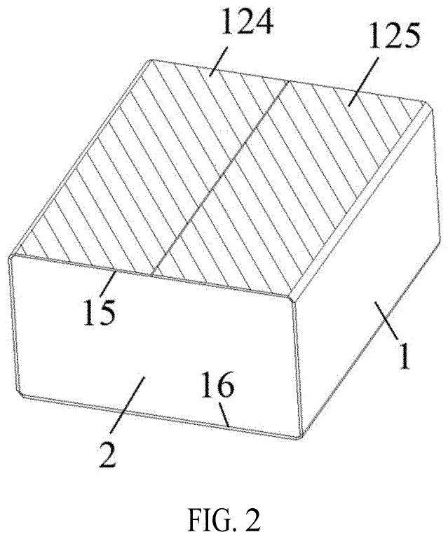

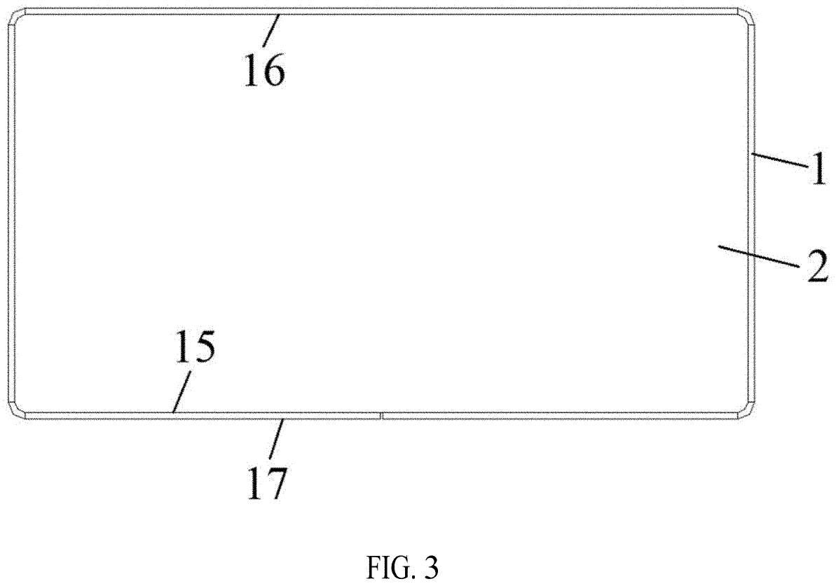

FIG. 1 is a three-dimensional illustration of an elastic thermal connection structure. FIG. 2 is another three-dimensional illustration of the elastic thermal connecting structure. FIG. 3 is a front view of the elastic thermal connection structure. The elastic thermal connection structure includes a heat dissipating layer 1 such as a graphite sheet outer layer and the others described herein and a foam inner layer 2 that comprise one or more foams and void mediums described herein. The heat dissipating layer 1 wraps the foam inner layer 2.

Some heat dissipating layers 1 comprises artificial graphite. The artificial graphite has a predetermined flexibility and flexes under tension to take on different shapes that wrap the inner layer 2 of foam. Exemplary artificial graphite has a high thermal conductivity that achieves a high heat dissipation. The disclosed foam material has good elasticity and a high density that retains its shape under long-term thermal and mechanical stress and conforms to different chip heights and surface areas. The elastic thermal connection structure does not require a rebound force to maintain its form and its vibration, electrical, and acoustical attenuating properties.

As shown, the heat dissipating layers 1 wraps the inner layer 2 of foam. The foam's elasticity ensures substantial contact with and between the chips and an exterior heat dissipating component (e.g., the heat sink). The elasticity of the foam and the void medium described herein ensure a stable and consistent thermal connection between the electronic components/chips and the exterior heat dissipating component. The exemplary system ensures a continuous heat dissipation and that guides the heat from the heating generating circuits and/or chips to a heat dissipation component.

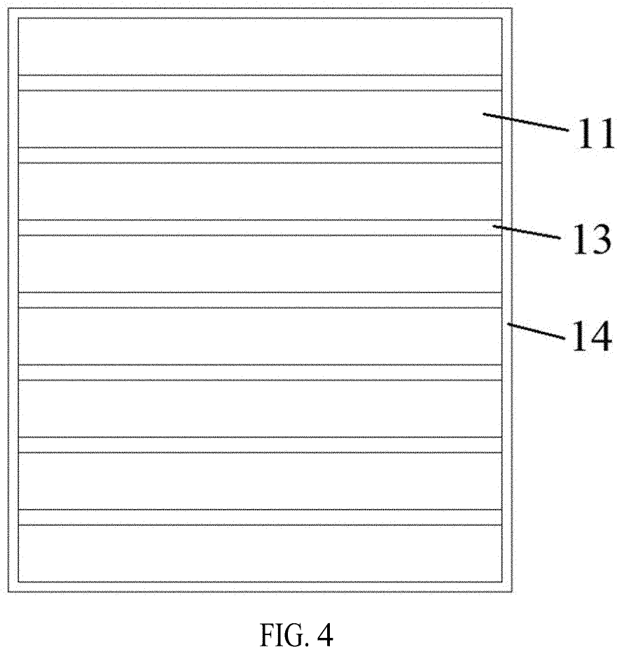

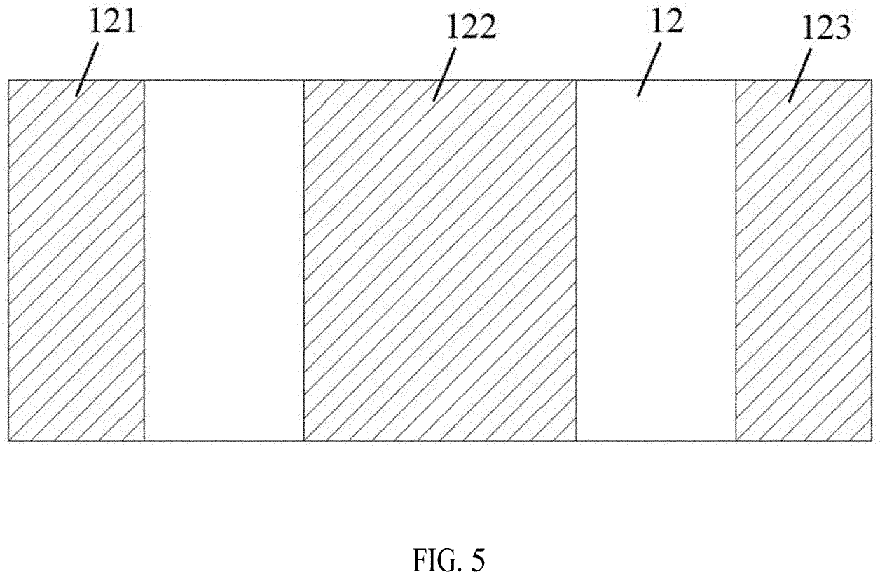

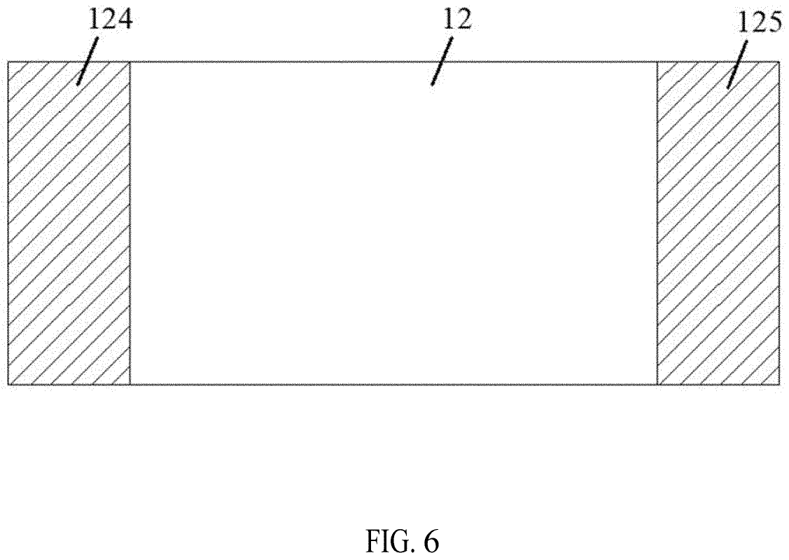

FIG. 4 is a heat dissipating layer. FIG. 5 is a top view of an outer layer. FIG. 6 is a bottom view of the outer layer. In another exemplary system, multiple layers 11 of carbonaceous material (many shown and one referenced in FIG. 4) are arranged in hexagonal flat layers compressed into a sheet outer layer 12 to form a heat dissipating layer 1. The materials that form layers 11 varies proportionally with the amount of heat (e.g., the amount of degrees) to diffuse. The dimensions and number of layers used are not a design choice as each serve a different function.

In another exemplary system, a graphite sheet comprises the heat dissipating layer 1. Graphite sheets used as multiple layers 11 (shown in FIG. 4) has a thermally conductivity of 1600 W/m*K and a thickness of 0.032 mm. The elastic thermal connection structure includes an optional radiator comprising a cast aluminum or copper. The radiator has thermal conductivity of about 200 W/m*k. To achieve a maximum thermal conductivity, the thickness of the aluminum plate is 1600*(0.032*8)/200=2.05 mm. In this exemplary system, the heat dissipating layer 1 comprises a graphite sheet and the left and right sides are positioned in a vertical and upward alignment to enhance heat conduction. The two sides are collectively about 2.05 mm*2=4.1 mm in thickness.

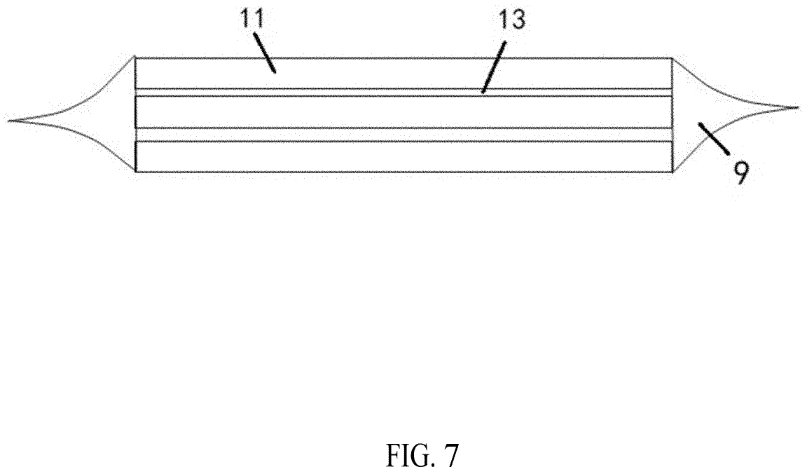

A multilayer heat dissipating layer such as multiple strip-shaped graphite sheet used as multiple layers 11 is layered through multiple double-sided rubberized PET sheets 13. One is referenced in FIG. 4. The surface forms an edge seal 14 formed by a spray film as shown in FIG. 4. When the layers 11 are combined they form the outer layer 12 shown in FIGS. 6 and 7.

FIG. 7 is a side view of the elastic thermal connection structure showing the layers 11 coupled with an adhesive sheet. In FIG. 7, an edge sealing of the film is formed by spraying to minimize damage. The bonded sheet shown as a layer 11 receive adhesive on a side of a PET sheet 9 to form a composite. The adhesive layered on a side of PET sheet 9 has a stronger abrasion resistance and forms outer layer 12.

As shown in FIG. 5, a top surface of the outer layer 12 includes a first adhesive area 121, and the middle of the top surface of the outer layer 12 includes a second adhesive area 122. The other side of the top surface of the outer layer 12 includes a third adhesive application area 123. The first adhesive area 121, the second adhesive area 122, and the third adhesive area 123 are joined with a double-sided rubberized PET sheet or by another adhesive.

In some systems, the outer layer 12 is subject to tension that forms the heat dissipating layer 1 and an inner wall. The first adhesive area 121 and the third adhesive area 123 comprise the inner wall bottom surface 15 of the heat dissipating layer 1, and the second adhesive area 122 comprise the top inner wall 16 of the heat dissipating layer as shown through FIGS. 2, 3 and 10. The inner layer 2 of foam is wrapped by a bottom surface of the inner wall bottom surface 15, a top surface of the inner wall 16, and the outer layer of the heat dissipating layer 1 by an adhesive.

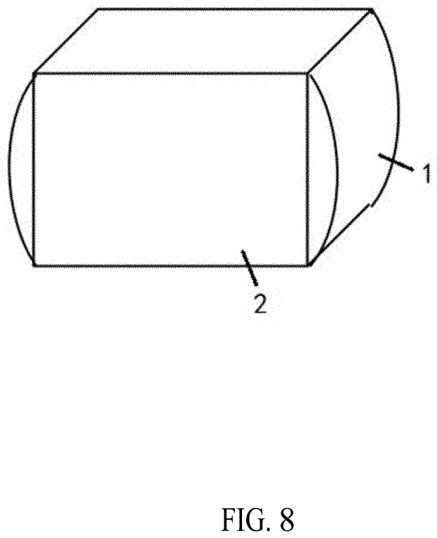

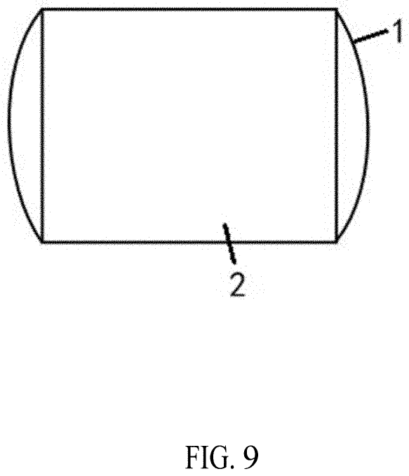

When the outer layer 12 of the heat dissipating layer 1 is formed, neither the inner wall left side surface nor the inner wall right side surface of outer layer 1 is coated with an adhesive. The left side of the inner wall and the right side of the inner wall of the outer layer 1 are also not fastened by adhesive on both sides. During the assembly, the heat dissipating layer 1 may be compressed and assembly may include a positioning of the heat dissipating layer 1. The right side of the inner wall or the entire inner wall can freely flex to facilitate the installation and/or absorb contractions and expansions of the electronic device. As shown in FIGS. 8 and 9, the elasticity of the heat dissipating layer 1 allows the heat dissipating layer 1 to rebound through the foam inner layer's elasticity, which ensure continuous physical contact between the heating components the heat dissipation components. In another system, a surface of the outer layer 12 includes a fourth adhesive receiving area 124 and the other side includes a fifth adhesive receiving area 125 as shown in FIG. 6.

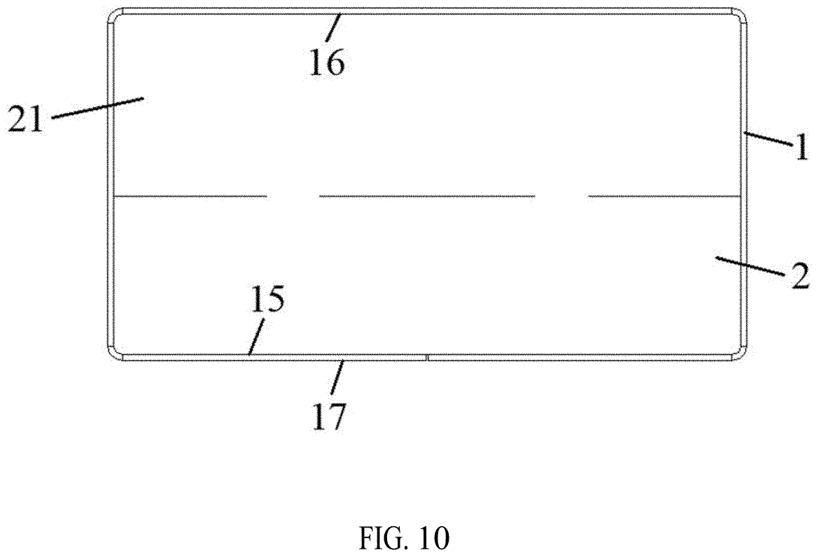

When the heat dissipating layer 1 is tensioned to a desired form, the bottom surface of the outer layer 12 forms the outer wall of the heat dissipating layer 1. The fourth adhesive area 124 and the fifth adhesive area 125 form the outer wall bottom surface 17 of the heat dissipating surface 1 as shown in FIGS. 6 and 10. In an exemplary system, the outer wall bottom surface 17 of the heat dissipating layer 1 can be bonded to the circuit components directly or through an electrical insulator having the same thermal resistivity of the circuit to ensure a strong thermal connection. In some systems, each side of the heat dissipating layer 1 is configured with rounded transitions.

In FIG. 10, the foam inner layer 2 may comprise a single-layer foam. The thickness of the single-layer foam can function like the mechanical filters described herein, conform to circuit geometries, and compensate for different heat conducting distances. Some systems customize the thickness and composition of the foam 2 and void medium as described herein. When a small amount of the elastic thermal connection structure is needed, the inner layer 2 of foam may comprise multiple layers 21 of foam as referenced in FIG. 10. The multiple layers 21 of foam accommodate circuit geometries, different heat conduction rates, and compensates for different distances.

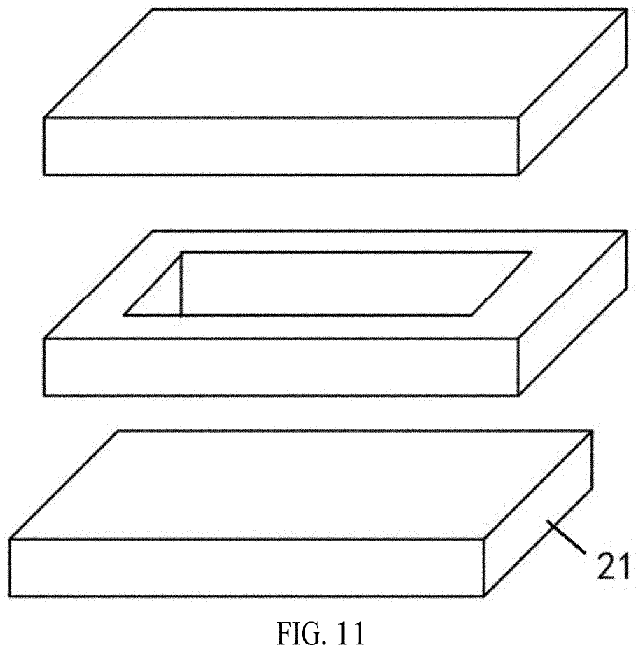

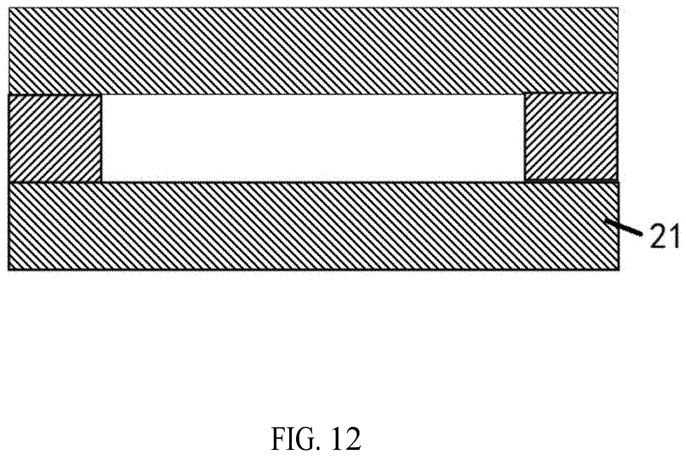

FIG. 11 is an exploded view of a multilayer foam. FIG. 12 is a cross-sectional view of multilayer foams showing contrasting lateral grain orientations. In these systems, the inner layer 2 of foam comprises multiple layers of foams 21 with different cross-sections that provide different mechanical, thermal, and electrical properties as described herein. In these systems, the inner layer 2 of foam biases an inner heat dissipating layer in direct physical contact with electrical components and chips and inner layer 2 of foam or couples the electrical components and chips. The inner heat dissipating layer is directly connected to or joined to the outer heat dissipating layer 1. In alternate systems, the inner heat dissipating layer conductively coupled to an outer heat dissipating layer 1 by an intermediate thermal connection. The resilient bias of the inner layer 2 of the foam assures physical contact between the circuits and chips and the outer heat dissipating layer 1. In some systems, outer heat dissipating layer 1 couples a heat sink or radiator. In some other systems, the inner layer 2 comprises the foam and void mediums described herein.

In an exemplary system, the heat dissipating layer 1 comprises a graphite sheet outer layer and the inner layer 2 comprises foam. The graphite sheet outer layer wraps the foam inner layer. Artificial graphite and foam materials provide strong elasticity and a strong thermal conductivity. The constant physical contact of the elements ensure a stable and reliable thermal connections between the circuit and chips.

Some alternate systems incorporate a grain boundary strengthening when the grain orientations are not continuous or homogenous as shown by the differing grain orientations shown in FIG. 12. A grain boundary strengthening significantly enhances unconstrained slip-based deformation caused by shear stress by applying a heat treatment followed by a cooling treatment and/or in some systems, applying an thermally conductive adhesive thereafter.

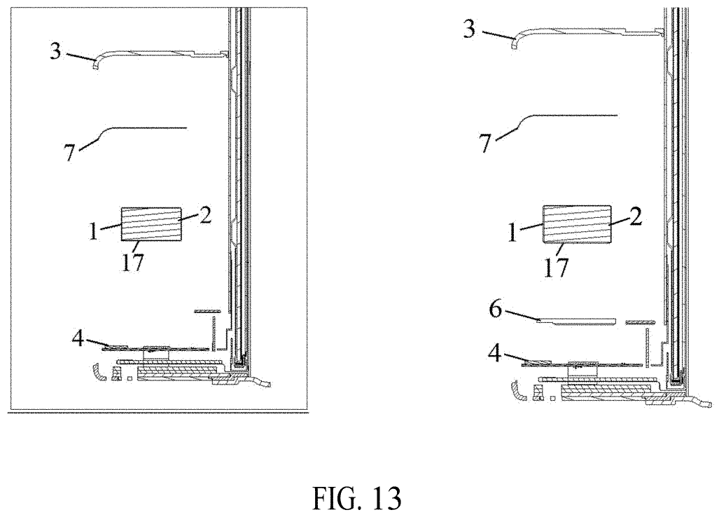

FIG. 13 is an exploded view of an exemplary machine. The exemplary machine comprises a housing 3, one or more chips 4, and graphite heat sink 7. An elastic thermal connection structure is positioned between the heat sink 7 and the chips 4. Several chips 4 couple the housing 3 through an internal surface. An elastic thermal connection structure is positioned between the chips 4 and the graphite heat sink 7. A bottom surface 17 of the outer wall of the heat dissipating layer 1 couples or bounds the chips 4 without making electrical contact with the conducting leads of the chips. In FIG. 13, the heat dissipating layer 1 comprises a graphite sheet.

In some systems shown in FIG. 13, the chips 4 comprises a single chip and in other systems, the chip heights are substantially the same. In these systems, the elastic thermal connection structure couples each of the chips and directly compensate for spacing. The foam bias of the elastic thermal connection structure directly couples or contacts the heat sink 7 to ensure a stable and reliable thermal connection.

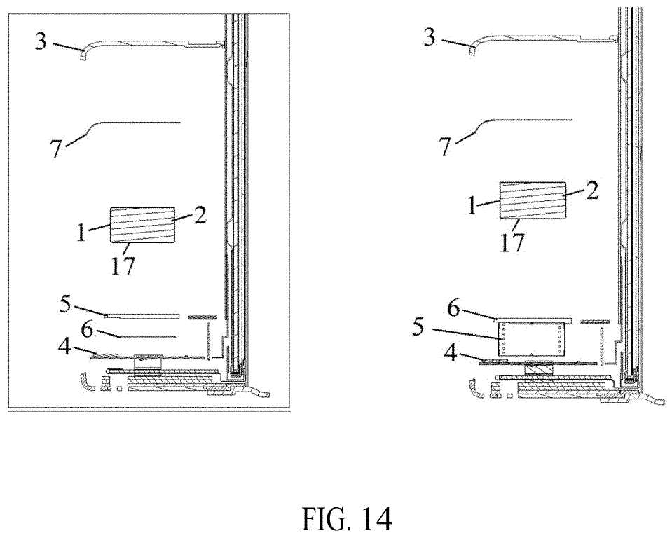

FIG. 14 is another exploded view of the machine. Chips 4 are coupled within or positioned within the housing 3. The chips 4 are positioned below a mounting platform 5 and a thermal pad 6. In FIG. 14, the elastic thermal connection structure is coupled to the mounting platform 5 through pad 6 and to the heat sink 7.

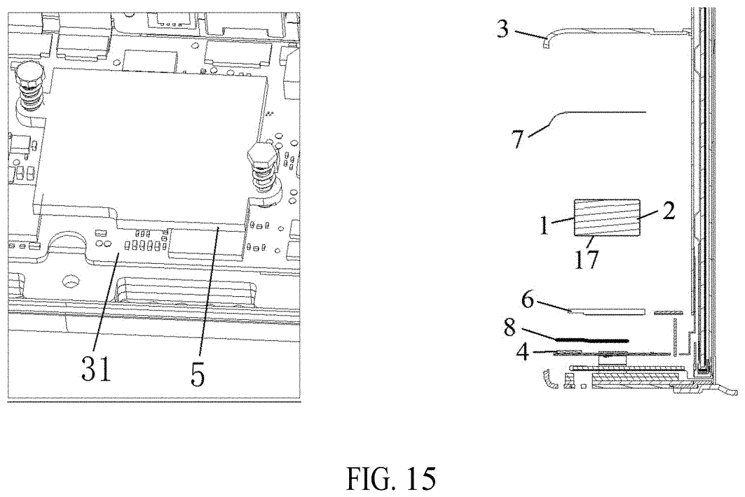

In FIG. 15, the machine includes a shell 3 and a motherboard 31. The chips 4 couple the motherboard 31 that couples the installation platform 5 through a thermally conductive electrically isolating connecting sheet 8. In this exemplary machine, height difference between the chips 4 are compensated by the flexible surface of installation platform 5 that couples a heat sink 7. In FIG. 15, the installation platform 5 comprises the elastic thermal connection structure.

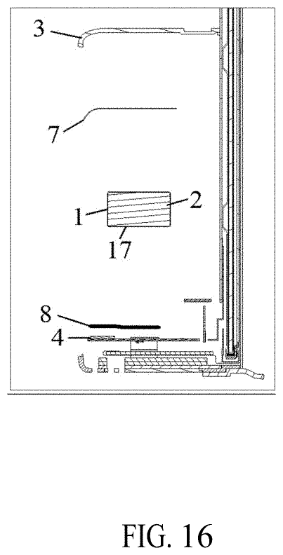

In FIG. 16, the chips 4 couple the thermal connection structure through the thermally conductive connecting sheet 8 within housing 3. A heat sink 7 in thermal contact with the thermal connection structure is positioned above chips. In FIG. 16 the chips 4 comprise the heating components and the housing 3 and heat sink 7 comprises a heat dissipating structure. The foam inner layer 2 within the elastic thermal connection structure ensures that the chips 4 couple the heat sink 7. In these systems, a reliable thermal connection is maintained between the heat dissipating layer 1, the chips 4, and the heat sink 7. The elastic thermal connection structure absorbs heat, absorbs compressions, and absorbs vibrations in addition to the other benefits recited in this disclosure. When an installation platform 5 supports chips 4, an adjacent thermal pad 6 shown in FIG. 14 provides a heat conduction path to the housing 3.

The systems disclosed herein may suitably be practiced in the absence of any element or component which is not specifically disclosed herein. They may operate in the absence of those elements. Further, the various elements described in each of the many systems described herein is regarded as divisible with regard to the individual elements and components described, rather than inseparable and required as a whole. In other words, alternate systems encompass any variation and combinations of elements described herein and may be made or used without the various elements described (e.g., they may operate in the absence of one or more of the elements disclosed herein and/or shown in FIGS. 1-16, and/or disclosed in the prior art but not recited herein).

The term “coupled” disclosed in this description may encompass both direct and indirect coupling. Thus, first and second parts are said to be coupled together when they directly contact one another, as well as when the first part couples to an intermediate part which couples either directly or via one or more additional intermediate parts to the second part (e.g., indirectly contacts). The term “substantially” or “about” encompasses a range that is largely (ninety five percent or more), but not necessarily wholly, that which is specified. It encompasses all but an insignificant amount such as within five percent. The term “near” means within a short distance (e.g., conventionally measured in centimeters) or interval in space or time.

The disclosed systems and machines compensate for mechanical and thermal stress. Using homogeneous flexible layers and/or mixed density flexible inhomogeneous layers, an elastic thermal connection structure or temperature control system provides thermal diffusivity and vibration compensation for electronic devices. The system's thermal diffusivity varies with the density and porosity of the flexible layer.

Using combinations of low and/or high thermal conductivity flexible materials, the systems control the heat transfer rates thorough electronic devices. When a foam layer is used, electrical insulating and thermal conducting medium or mediums that is/are injected within the foam's closed cells and/or voids or are part of the foam itself becomes more excited as the temperature increases. As temperature increase, convection increases within the foam and between the cells and the voids, increasing the thermal convection and heat transfer flow to a heat dissipating outer layer that dissipates the heat to an open area directly or through a heat sink or radiator.

In some systems, the thermal conductivity of the foam layer is substantially continuous when the foam and the void medium comprise homogeneous thermal conductors, respectively. In other systems, the thermal conductivity across electronic devices vary due to the foam layer's inhomogeneity, grain structure, and/or the various thermal conducting properties of the different mediums used within different parts of the foam, or enclosed in different cells and/or voids and the heat dissipating layer.

In some systems, the foam layers use high thermal conducting materials in some parts and insulating materials in other parts of the foam layers to sustain an optimum operating temperature. Some foam uses amorphous mediums within the foam itself, and/or enclosed within cells and/or voids that vary near or at different parts of a circuit, electronic components, and/or an electronic device.

Other systems, methods, features and advantages will be, or will become, apparent to one with skill in the art upon examination of the figures and detailed description. It is intended that all such additional systems, methods, features and advantages be included within this description, be within the scope of the disclosure, and be protected by the following claims.

What is claimed is:

1. A thermal connection structure, comprising:
a foam layer comprising a light porous, semi-grid flexible material;
a thermal conducting medium injected within closed cells and voids of the foam layer; and
a heat dissipating layer that couples the thermal conducting medium comprising a planar unsaturated ring that has thermal conductivity of at least 1.3 W m⁻¹ K⁻¹.

2. The thermal connection structure of claim 1 where the heat dissipating layer encloses the thermal conducting medium.

3. The thermal connection structure of claim 1 where the heat dissipating layer couples a heat sink.

4. The thermal connection structure of claim 1, where a mean foam pore size lies at or between 100-200 μm and comprises a density of 5 mg⁻³.

5. The thermal connection structure of claim 4 where the thermal conducting medium comprises graphene and metallic particles that increase thermal conductivity of the graphene by more than fifty percent.

6. The thermal connection structure of claim 5 where the foam layer is electrically tuned to function as a mechanical equivalent of an electrical notch filter.

7. The thermal connection structure of claim 5 where the foam layer is electrically tuned to function as a mechanical equivalent of an electrical lowpass filter.

8. The thermal connection structure of claim 5 where the foam layer is electrically tuned to function as a mechanical equivalent of an electrical high pass filter.

9. The thermal connection structure of claim 5 where the heat dissipating layer comprises one-atom-thick aromatic crystal linked in a hexagonal lattice.

10. The thermal connection structure of claim 9 where the links comprise covalent bonds separated by only about 0.142 nanometers.

11. The thermal connection structure of claim 9 where the foam layer comprises an electrical conductor.

12. The thermal connection structure of claim 11 where the foam layer comprises an electrical insulator.

13. The thermal connection structure of claim 12 where the foam layer is in direct physical contact with an electronic circuit.

14. The thermal connection structure of claim 12 where the foam layer is in indirect contact with an electronic circuit.

15. An elastic thermal connection structure, comprising:
a foam layer comprising a light porous, semi-grid flexible material;
a thermal conducting medium injected within cells and voids of the foam layer; and
a heat dissipating layer that couples the thermal conducting medium comprising a planar unsaturated ring that has thermal conductivity of at least 1.3 W m⁻¹ K⁻¹;
wherein the heat dissipating layer fully encloses thermal conducting medium.

16. The elastic thermal connection structure of claim 15, where the heat dissipating layer comprises a plurality of graphite sheets.

17. The elastic thermal connection structure of claim 16, wherein the plurality of graphite sheets are adhesively bonded by a double-sided rubberized polymer polyethylene terephthalate sheet with an adhesive on both sides of the graphite sheets and, wherein the plurality of graphite sheets are sealed by a spray film.

18. The elastic thermal connection structure of claim 17, where a mean foam pore size lies at or between any value between 100-200 μm and comprises a density of 5 mg⁻³.

19. The thermal connection structure of claim 18 where the thermal conducting medium comprises a mixture of graphene and silver.

20. The thermal connection structure of claim 5 where the foam layer is electrically tuned to function as a mechanical equivalent of an electrical notch filter or an electrical high pass filter.
